(19) United States
(12) Patent Application Publication
(10) Pub. No.: US 2008/0186495 A1
(43) Pub. Date: Aug. 7, 2008

(54) Cylindrical waveguide biosensors

(75) Inventors: Shalini Prasad, Portland, OR (US); Ravi Kiran Reddy, Portland, OR (US)

Correspondence Address: KLARQUIST SPARKMAN, LLP, 121 SW SALMON STREET, SUITE 1600, PORTLAND, OR, 97204, US

(73) Assignees: State of Oregon acting by and through the State Board of Higher Education on behalf of Portland; State University

(21) Appl. No.: 11/891,650

(22) Filed: Aug. 9, 2007

Related U.S. Application Data
(63) Continuation-in-part of application No. 11/634,367, filed on Dec. 4, 2006.
(60) Provisional application No. 60/742,010, filed on Dec. 2, 2005.
(60) Provisional application No. 60/778,636, filed on Feb. 27, 2006.
(60) Provisional application No. 60/793,372, filed on Apr. 19, 2006.
(60) Provisional application No. 60/742,010, filed on Dec. 2, 2005.
(60) Provisional application No. 60/778,636, filed on Feb. 27, 2006.
(60) Provisional application No. 60/793,372, filed on Apr. 19, 2006.

(51) Int. Cl. G01N 21/00; G03F 1/00; G03F 7/20

(52) U.S. Cl. 356/440; 430/325; 430/326; 430/321

(57) ABSTRACT

Sensors include a substrate having defined thereon at least one polymer optical cavity with a sensitizing agent such as antibodies immobilized on the exterior of the polymer optical cavity. The polymer optical cavity can be defined in a polymer layer that is spin coated onto a substrate and photolithographically exposed. Positive or negative photoresists can be used to define the polymer optical cavity.

### CROSS REFERENCE TO RELATED APPLICATIONS

This application is a continuation-in-part of U.S. application Ser. No. 11/634,367, filed Dec. 4, 2006, that claims the benefit of U.S. Provisional Application No. 60/742,010, filed Dec. 2, 2005, U.S. Provisional Application No. 60/778,636, filed Feb. 27, 2006, and U.S. Provisional Application No. 60/793,372, filed Apr. 19, 2006, all of which are incorporated herein by reference.

### FIELD

The disclosure pertains to biosensors based on sensitized polymer optical cavities.

### BACKGROUND

Genomics and proteomics research has identified biomarkers that can be used in the detection and treatment of many diseases. Disease assessment can be based on one or many biomarkers, and in some cases, different biomarkers may be appropriate for different disease stages. Such biomarkers can be used to assess disease progress and aid in determining treatment as well as in judging the effectiveness of a course of treatment. Accordingly, biomarker based measurements can permit improved patient care.

Unfortunately, biomarker based measurements can be slow, expensive, or otherwise impractical. Conventional methods used with biomarkers are typically based on gel electrophoresis, enzyme-linked immunosorbent assays (ELISAs), plasma resonance, or other techniques. These methods generally have limited sensitivity, slow response, and lack specificity. Thus, although biomarkers offer promise for improved disease treatment and diagnosis, these advantages have not been realized in practice, and improved methods and apparatus are needed.

### SUMMARY

Biomarker detectors can be fabricated based on sensitized polymer waveguides formed on a suitable substrate. In one example, sensors comprise a substrate having defined thereon at least one polymer optical cavity and a sensitizing agent immobilized on at least a portion of an exterior of the polymer optical cavity. In some embodiments, a first polymer waveguide is coupled to the polymer optical cavity and configured to deliver an optical interrogation flux to the polymer optical cavity and a second polymer waveguide is coupled to the polymer optical cavity and configured to receive an optical flux modulated based on the first sensitizing agent. In typical examples, the polymer optical cavity is formed of a polymer photoresist. In some examples, the substrate comprises a silica layer and the polymer optical cavity is situated adjacent the silica layer. In representative embodiments, the polymer optical cavity is a cylindrical cavity having a diameter between about 100 μm and 1.0 mm. In additional examples, the polymer photoresist is a positive resist or a negative resist, and the sensitizing agent is associated with at least one of CRP and MPO.

Sensor systems comprise a sensitized polymer optical cavity and a light source coupled to provide an interrogation light flux to the polymer optical cavity. A detection system is configured to receive a portion of the interrogation light flux modulated in response to an analyte from the sensitized polymer cavity and provide an indication of an analyte concentration based on the received portion. In some examples, an input waveguide is configured to couple the interrogation light flux from the light source to the sensitized polymer cavity and an output waveguide is configured to couple the modulated portion to the detection system. In additional examples, the input waveguide and the output waveguide are of unitary construction with the polymer optical cavity.

Methods comprise applying a photopolymer layer to a substrate and exposing the photopolymer layer to a patterned light flux associated with at least one optical cavity. The photopolymer is developed so as to define the at least one optical cavity, and a sensitizer is applied to the at least one optical cavity. In some examples, the photopolymer layer is a photoresist layer and the sensitizer is associated with selective bonding of at least one of MPO or CRP. In some particular embodiments, the photoresist is a positive resist or a negative resist. In additional representative embodiments, the patterned light flux is associated with the at least one optical cavity and at least one waveguide coupled to the at least one optical cavity, and the photopolymer is developed so as to define the at least one optical cavity and the at least one waveguide. In a particular example, the optical cavity is cylindrical.

The foregoing and other objects, features, and advantages of the disclosed technology will become more apparent from the following detailed description, which proceeds with reference to the accompanying drawings.

### BRIEF DESCRIPTION OF THE DRAWINGS

FIG. 1 is a schematic diagram of a sensor that includes a nano-membrane secured to a base substrate.

FIG. 2 is a schematic representation of a surface of an alumina nano-membrane.

FIG. 3 is a schematic diagram of a sensor that includes a plurality of sensitized regions.

FIG. 4 is a schematic diagram of a surface of a base substrate configured for attachment of an alumina nano-membrane.

FIG. 5A is a block diagram of a representative method of forming alumina nano-membranes.

FIG. 5B illustrates exposure of an aluminum foil to an electrolyte bath for formation of an alumina nano-membrane.

FIGS. 6A-6B illustrate a sensor that includes a nano-membrane retained in a channel in a silicon substrate.

FIG. 7 illustrates a sensor apparatus that includes a sensor and a spectrum analysis system.

FIG. 8 is a schematic diagram of a sensor that includes a membrane secured to a base substrate.

FIGS. 9A-9D illustrate spectra obtained with CRP antibody sensitized devices illustrating a detection signature based on spectral peaks at 362 Hz and 588 Hz.

FIGS. 10A-10D illustrate spectra obtained with MPO antibody sensitized devices illustrating a detection signal based on spectral peaks at 180 Hz and 365 Hz.

FIG. 11 is a sectional view of a representative sensor.

FIG. 12 illustrates a sensor assembly that includes an array of sensitized membrane sensors.

FIG. 13 illustrates a nano-porous membrane on which two sets of nano-pores are coupled to respective conductors.

FIG. 14 is sectional view of a substrate on which a photoresist-based sensitized optical cavity is formed.

FIG. 15 is a schematic diagram of an interrogation system for a sensitized optical cavity.

FIG. 16 is a plan view of an additional example of a sensitized optical cavity that includes input/output waveguides.

### DETAILED DESCRIPTION

As used in this application and in the claims, the singular forms “a,” “an,” and “the” include the plural forms unless the context clearly dictates otherwise. Additionally, the term “includes” means “comprises.” Further, the term “coupled” means electrically, electromagnetically, or fluidically coupled or linked and does not exclude the presence of intermediate elements between the coupled items.

The described systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

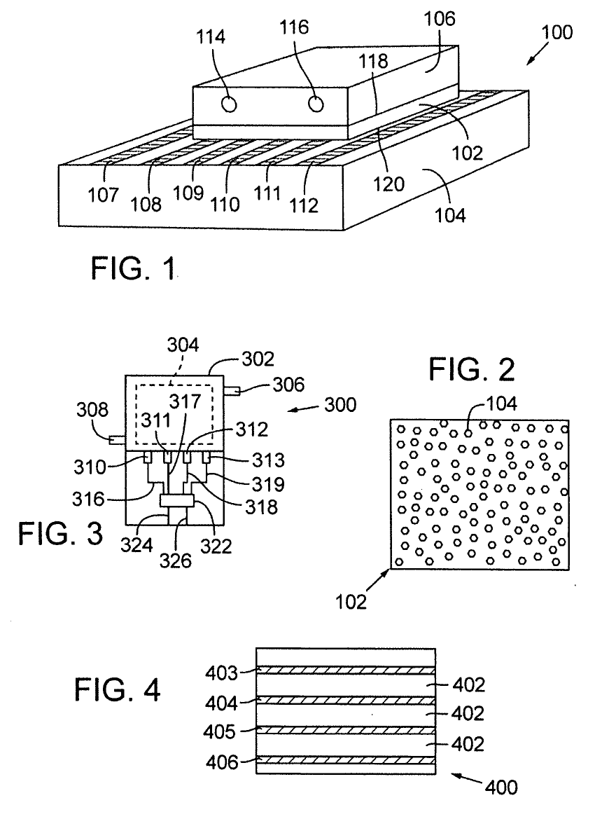

Referring to FIG. 1, a sensor 100 includes a nano-membrane 102 (described in detail below) that is secured to a base substrate 104. A fluid chamber 106 is placed on the nano-membrane 102, and includes an inlet port 114 and an exit port 116 and is situated so that a first surface 118 of the nano-membrane is exposed to reagents provided to the fluid chamber 106 through the inlet port 114. Fluid chamber volume can be selected based on, for example, a convenient specimen volume, and is typically between about 1 μl and 1000 μl. Conductor strips 107-111 are provided on the base substrate 104, and are electrically coupled to respective portions of a second surface 120 of the nano-membrane 102. The nano-membrane 102 includes a plurality of nano-pores that couple the first and second surfaces 118, 120. For convenience, the conductors 107-111 are shown as linear segments that are covered by the nano-membrane 102 but that extend on both sides of the nano-membrane 102. In other examples, different conductor shapes can be used, and the conductors need not extend on both sides (or either side) of the nano-membrane. In other examples, electrical connections can be made through the base substrate. As shown in FIG. 1, a conductor strip 112 is provided as a reference conductor, and is not directly electrically coupled to the nano-membrane 102. Other conductors or additional conductors can be configured as reference conductors as well by, for example, coupling such conductors to unsensitized nano-pores in the nano-membrane or to nano-pores that are blocked to remain unaffected by specimen portions in the fluid chamber 106.

In a convenient example, the nano-membrane 102 is an alumina membrane formed from an aluminum foil, and gold conductor strips are patterned and formed on the base substrate 104 using contact photolithography. Other membrane materials can be used, and conductors of silver, gold, copper, or other conductor or semi-conductor materials can be used. The fluid chamber is formed of polydimethoxysilane (PDMS), but other materials can be used. Alternatively, the chamber 106 can be omitted and test materials dispensed directly onto the first surface of the nano-membrane 102.

FIG. 2 is a schematic representation of a surface of a nano-membrane 102. The nano-membrane 102 typically includes a plurality of pores 104 having effective diameters of about 10 nm to 500 nm. The pores can have circular, elliptical, hexagonal, cross-sections, or cross-sections of other shapes. In certain applications, pore diameter is substantially uniform or variable within a predetermined range. The nano-membrane 102 is preferably an electrical insulator so that the pores 104 are not electrically coupled to each other absent addition electrical connections such as the conductor strips 107-111.

The base substrate 104 is generally an insulator, or includes an insulator portion. For example, silicon with an oxide layer can serve as the base substrate, wherein the conductor strips are defined on or in the oxide layer so as to be substantially electrically isolated. Such a base substrate can be especially convenient for inclusion of detection electronics in the base substrate. However, other substrate materials such as glass, fused silica, polycarbonate, polyimides, ceramics, epoxy, plastics, or the like can be used.

In an example, the base substrate is formed using a 2 cm by 2 cm section of silicon wafer cleaved from a larger wafer. This substrate is cleaned in piranha solution, spin coated with a positive photoresist, and a quartz photomask is used to define features 1 μm by 2 cm. A 10 nm thick gold film is sputter coated onto the photoresist, and gold conductor strips 2 μm by 2 cm can be formed using a lift off process. FIG. 4 illustrates conductive strips 403-406 with gaps 402 formed on a surface of a base substrate 400.

FIG. 3 is a schematic view of a representative multi-analyte sensor 300 that includes a membrane 304 secured to a base substrate 302. Fluid ports 306, 308 are configured to direct samples to the membrane 304. The membrane has sets of pores that are coupled to respective conductors 310-313 defined on the base substrate 302. The conductors 310-313 are electrically coupled to a multiplexer or switch 322 via interconnections 316-319 that can be conductor segments on the base substrate 302 or other electrical connections. The multiplexer 326 has signal outputs 322, 324 that are configured to provide electrical signals associated with selected sets of pores to a signal analysis system. Typically, a signal associated with a specific pore sensitization and a reference signal are provided.

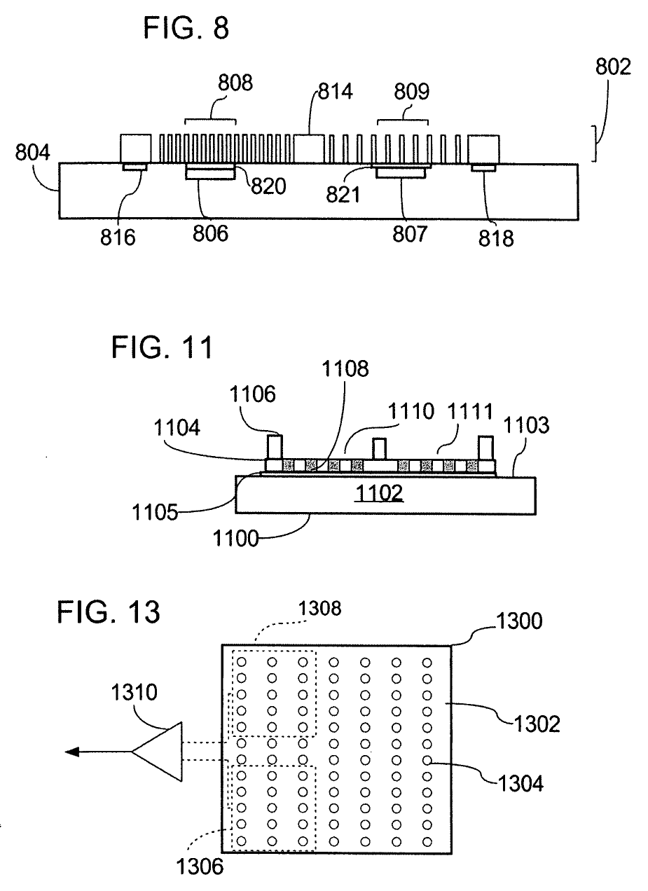

FIG. 8 is a sectional view of a representative sensor that includes a nano-porous membrane 802 and a base substrate 804. The base substrate 804 includes conductor strips 806, 807 that are coupled to a first set 808 and second set 809 of nano-pores, respectively. The conductor strips are separated by additional nano-pores and a region 814 without nano-pores. The nano-membrane 802 is secured to the base substrate 804 with a conductive silver paint deposited at predetermined attachment locations 816, 818. In other examples, carbon paint, epoxies, heat bonding, or anodic bonding can be used. For adhesive bonding, a portion of the substrate is dedicated to bonding, and the substrate can be made larger that an intended active area to provide a bonding region. In a typical example, a width of the conductor strips is 10-10⁴ times smaller than the spacing between the conductor strips 806, 807 so that the nano-pores coupled to the conductor strips 806, 807 are electrically isolated, and electrical signals at the conductor strips 806, 807 depend only on electrical processes in the sets 808, 809. As shown in FIG. 8, sensitizing layers or sensitizing agents 820, 821 are situated at the conductors 806, 807, respectively, and on surfaces of the pores of the sets 808, 809. Different types of sensitizing agents can be used. For example, one or more antibodies or antibody compositions can be immobilized on the conductors or in the nanopores. As shown in FIG. 8, pores of different diameters are provided in a single membrane. In addition, conductors are shown as defined in a base substrate, but typically conductors are formed on a substrate surface.

### Alumina Membrane Fabrication

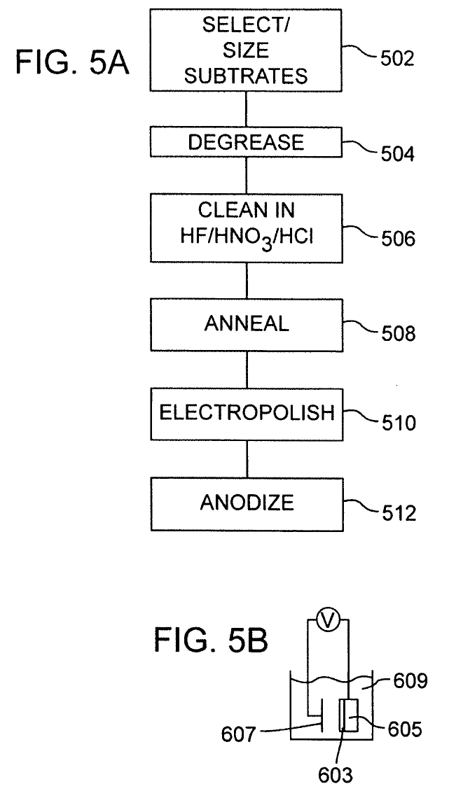

A representative method of membrane fabrication is outlined in FIG. 5A. High purity aluminum foil substrates (99.99% pure) are selected and sized in a step 502, degreased in acetone in a step 504, and cleaned in an aqueous solution of HF, HNO₃, and HCl in a volume ratio of about 1:1:2.5 in a step 506. After cleaning, the substrates are annealed in a nitrogen ambient at 400° C. for about 45-60 min. in a step 508 to remove mechanical stresses and allow re-crystallization. Grain sizes can be measured using electron microscopy, and grain sizes in the annealed substrates are typically between about 100 nm and 200 nm. Surfaces of the annealed substrates are electro-polished in step 510 in a mixture of HClO₄ (perchloric acid) and C₂H₅OH (ethanol). In a step 512, the substrates can be anodized at a constant cell potential in aqueous H₂SO₄ (sulfuric acid) at concentrations of between about 1.8 M and 7.2 M. Sulfuric acid/oxalic acid mixtures can also be used. Typical mixtures are combinations of 0.3 M oxalic acid with 0.18 M to 0.5 M sulfuric acid. Current densities typically range from about 50-100 mA/cm².

Multi-step anodizations can also be used. In a typical two step anodization, a first step is used to form a concave texture, and a second step is used to form nanostructures, typically at locations at which texture changes were formed in the first step. In a typical first anodization, the aluminum substrates are mounted on a copper plate anode, and a graphite plate is used a cathode. During anodization, the electrolyte is vigorously stirred and/or recycled, and cell voltage, current, and temperature are monitored and recorded. In this first anodization, cell potential is fixed at about 40 V and the substrates are exposed to 0.3 M oxalic acid (H₂C₂O₄) electrolyte solution for about 3 hrs at about 25° C. In a second anodization, partially anodized substrates are exposed to a mixture of 6% by weight of phosphoric acid and 1.8% by weight chromic acid for about 10 hrs at a temperature of about 60° C. After this second anodization, the first anodization is repeated for about 5 hrs. Pores are generally about 20 nm wide and about 25 nm deep. Any remaining aluminum in the substrates can be removed with a saturated mercuric chloride solution.

FIG. 5B illustrates anodization. An aluminum substrate 603 is secured to a copper plate 605 that serves as an anode. A graphite plate 607 is used as a cathode, and the aluminum substrate/copper plate and graphite plate 607 are exposed to an electrolyte solution 609 at a selected applied voltage. Electrolyte solution temperature, composition, and concentration, and applied voltage are selected to provide an intended pore size, aspect ratio, and/or pore density.

In typical examples, nanopores having diameters of about 25, 50, and 100 nm are produced using cell voltages of about 12 V, 25 V, and 40 V, respectively, at a cell temperature of about 60° C. Current density varies from about 1.2 A/cm² to 5 A/cm². Pore densities can be varied from about 6·10⁸/cm² to about 5·10¹⁰/cm², and are typically directly proportional to current density and inversely proportional to cell temperature.

In the second anodization step, varying the electrolyte temperature from 25° C. to 50° C. in increments of 1° C. for every 10 minutes permits selection of pore widths in a range of about 12 nm to 200 nm. Varying the applied voltage from 40 V to 70 V at 5 V increments every 10 minutes permits selection of pore surface density in a range of about 10⁵ pores/mm² to 10¹⁵ pores/mm², and pore depth can be altered from about 10 nm to 250 nm by increasing the voltage. By varying the concentrations of oxalic, phosphoric and chromic acids from about (1:0.5:0.5) by volume to about (2:3:3) by volume, pore width can be varied from about 12 nm to 750 nm. Specific combinations of these conditions can be used to obtain selected pore dimensions and pore densities. These conditions are summarized in Table 1 below.

TABLE 1
Processing Ranges for Pore Width, Depth, and Density

| Parameter | Range (from) | | Range (to) | | Feature |
|---|---|---|---|---|---|
| Temperature | 25° | C. | 50° | C. | Pore width: 12 nm-200 nm |
| DC voltage | 40 | V | 70 | V | Pore depth: 10 nm-250 nm |
| | | | | | Pore surface density: |
| | | | | | 10⁵ pores/mm² to |
| | | | | | 10¹⁵ pores/mm² |

| | | | |
|---|---|---|---|
| Acid ratio | 1:0.5:0.5 | 2:3:3 | Pore width: 12 nm to |
| | | | 750 nm |

Pores typically nucleate at surfaces of the substrates at approximately random locations, and pores have random locations and a broad distribution of sizes. Under certain specific conditions, a hexagonal ordering of pores is produced. These pores are well suited for trapping of nanometer sized particles. Pore sizes for a particular application can be selected based on a protein size so that the target protein “fits” the pores. Such a fit can reduce non-specific binding events, increasing measurement sensitivity and reliability.

### Detection Methods

Sensors can be interrogated by coupling one or more conductor strips as shown in FIG. 7. A sensor 700 includes a plurality of conductors 702-704 that are coupled to a multiplexer 706 that selects one or more of the conductors for coupling to a buffer amplifier 708. The multiplexer 706 can be controlled for such selection based on a user selection or under control of a desktop, laptop, or palmtop computer indicated as a controller 710 in FIG. 7. Alternatively, each conductor can be coupled to a respective buffer amplifier, and signals on all conductors made simultaneously available for signal analysis. In other examples, a mechanical switch or probe can be used to selectively couple to one or more conductors.

The conductors 702-704 can be associated with different sensitizations (for example, contacted to nano-pores on which different types of antibodies are immobilized.). Electrical signals from the conductors 702-704 are based on, for example, effective conductance variations associated with binding of antigen-antibody complexes. These electrical signals exhibit complex time domain behavior, but generally have characteristic features or “signatures” when viewed in the frequency domain. Typically, a specific bound complex is associated with one or more characteristic frequencies, and signal magnitude at the characteristic frequency (or frequencies) is a function of analyte concentration.

Characteristic frequencies can be detected with a spectrum analyzer 712 that is coupled to the selected conductor (or conductors) and that receives an electrical signal associated with the sensitized conductors/nano-pores. The spectrum analyzer 712 can be implemented using a mixer and a swept oscillator with a detector that is coupled to evaluate a magnitude and/or phase of a difference or sum frequency from the mixer. Alternatively, a time record of the coupled electrical signal can be stored, and a spectrum obtained using, for example, a fast Fourier transform. In some examples, a power spectrum is obtained in order to identify presence of a targeted material, or a response to a compound under investigation. A differential electrical signal is generally used such that a difference signal associated with a reference conductor and a conductor coupled to sensitized nano-pores is evaluated. Signals are generally available within seconds after exposure of a sensitized membrane to an analyte, and thus permit rapid analyte assessment. A signature analysis processor 714 is generally coupled to receive the detected spectra and, based on signatures stored in a signature database 716, determine presence and/or concentration of one or more analytes.

In one example, one or more specific protein biomarkers are bound to one or more nano-porous membranes that have been treated with an antibody receptor. Detected voltage variations are based on binding of the antibody-antigen protein complex to a base substrate. As an example, protein biomarkers associated with plaque rupture can be selected. These biomarkers can be used to assess perioperative ischemia which can be a predictor of surgical outcome. Selected biomarkers can be C-reactive protein (CRP) and myeloperoxidase (MPO). Purified samples of CRP, anti-CRP, MPO, and anti-MPO can be lyophilized from 0.01 M phosphate buffered saline solution (PBS) and 20 mM sodium acetate buffer, respectively, at a pH of about 7.2. CRP and MPR concentrations typically range from about 10 mg/ml to 50 ng/ml. Serum spiked samples include both proteins reconstituted in 20% human serum.

Base substrates and/or nano-porous membranes can be coated and incubated at about 37° C. for about 2 minutes. The base substrate can be selectively coated with bovine serum albumin (BSA) having a concentration of about 2 μg/ml in non-metallic areas and washed with PBS to reduce detection of non-specific binding. Pores can be selectively sensitized using micro injection techniques based on ink jet printing that can produce streamed liquid droplets in sizes ranging from about 1 μm to 5 μm. Volumes up to 500 ml can typically be dispensed from a single ink jet before ink jet replenishment is needed. Alternatively, antibodies in liquid form can be extracted from glass micro capillaries of pore widths of about 1-2 μm using vacuum suction. Extracted volumes are typically about 100 μL. Micro syringes can also be used to manually transfer specific antibodies to selected regions. Micro syringe volumes are typically about 5 μL.

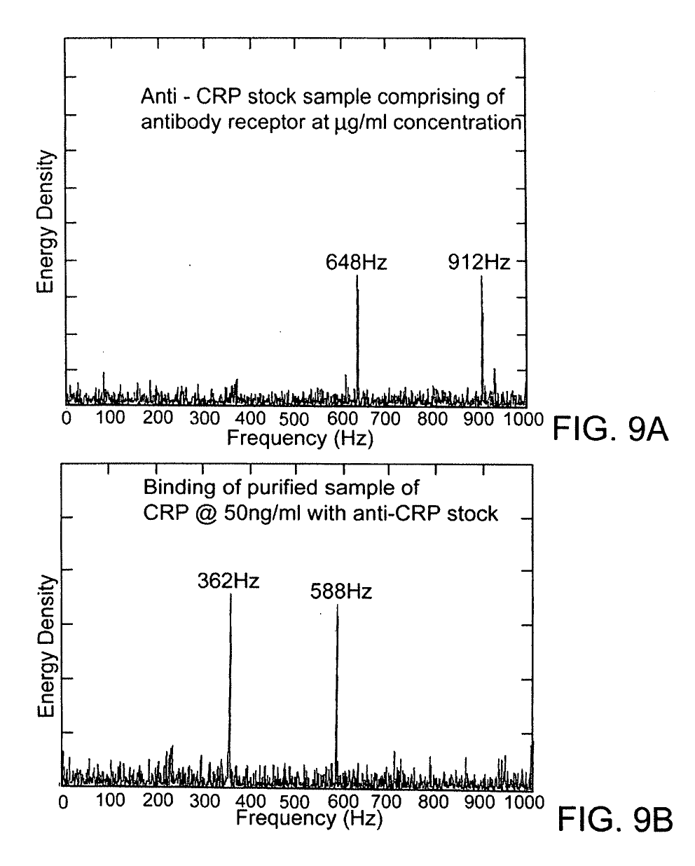

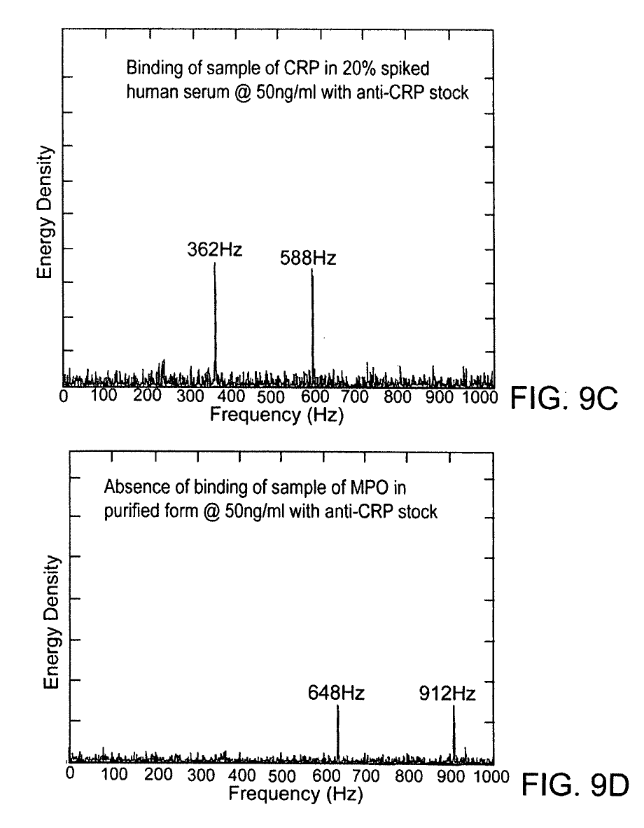

Response of sensors sensitized with CRP antibodies were measured with no additional analyte exposure, with exposure to test CRP samples, as well as an MPO containing specimen to determine non-specific binding. Representative spectra are illustrated in FIGS. 9A-9D. FIG. 9A illustrates response of a CRP antibody sensitized device (sensitized with a 1 μg/ml antibody solution) without analyte exposure. Characteristic spectral peaks are observed at 648 Hz and 912 Hz. FIGS. 9B-9C illustrate response of CRP antibody sensitized devices exposed to purified CRP samples (50 ng/ml) and a sample of CRP in 20% spiked human serum (50 ng/ml). Characteristic spectral peaks are apparent at 362 Hz and 588 Hz. FIG. 9D illustrates response of CRP antibody sensitized devices to purified MPO solution (50 ng/ml). The same spectral peaks as noted in FIG. 9A are apparent, indicating that MPO does not interfere with CRP detection.

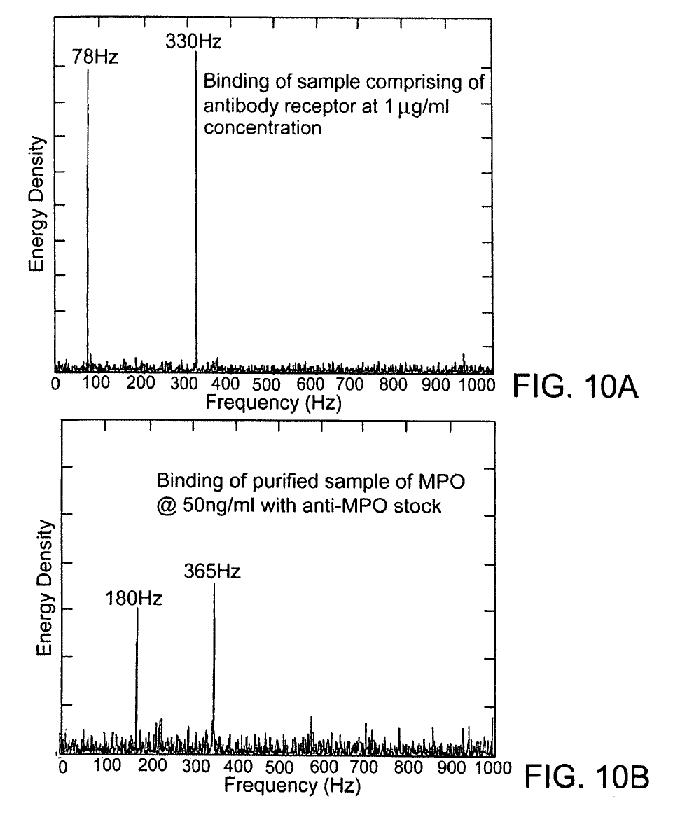

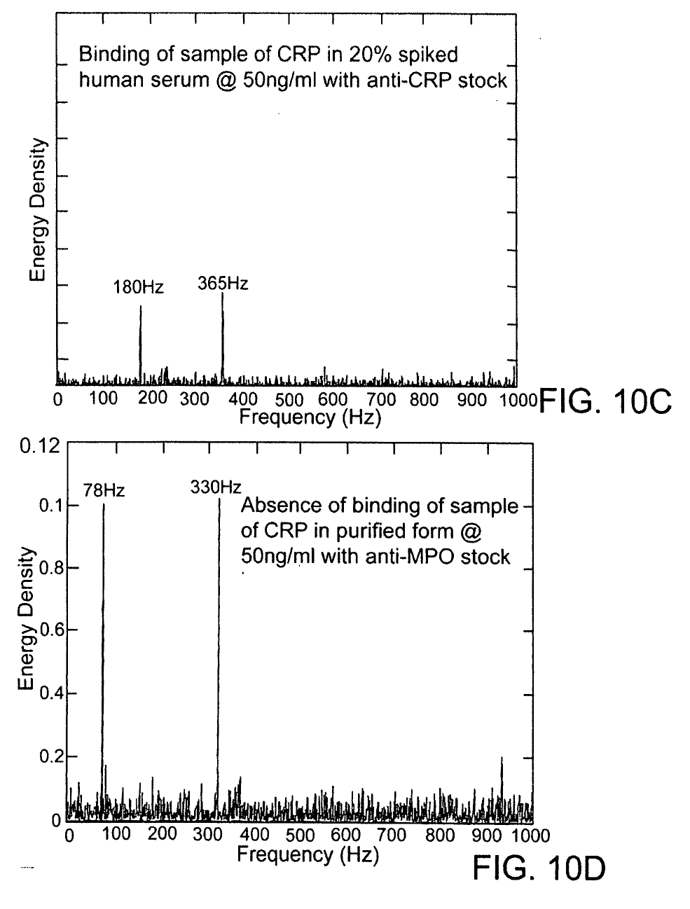

Similar results for MPO antibody sensitized devices are illustrated in FIGS. 10A-10D. FIG. 10A illustrates response of an MPO antibody sensitized device (sensitized with a 1 μg/ml antibody solution) without analyte exposure. Characteristic spectral peaks are observed at 78 Hz and 330 Hz. FIGS. 10B-10C illustrate response of MPO antibody sensitized devices exposed to a purified MPO sample (50 ng/ml) and a sample of MPO in 20% spiked human serum (50 ng/ml). Characteristic spectral peaks are apparent at 180 Hz and 365 Hz. FIG. 10D illustrates response of MPO antibody sensitized devices to purified CRP solution (50 ng/ml). The same spectral peaks as noted in FIG. 10A are apparent, indicating that CRP does not interfere with MPO detection. For both CRP and MPO sensitized devices, signal to noise ratio is a function of CRP or MPO concentration, respectively.

Response signatures are summarized in Table 2 below.

TABLE 2
MPO and CRP Signature Frequencies

| | Analyte | | |
|---|---|---|---|
| Antibody | CRP | MPO | None |
| Anti-CRP | 362/588 | 648/912 | 648/912 |
| Anti-MPO | 78/330 | 180/365 | 78/330 |

### ADDITIONAL EXAMPLES

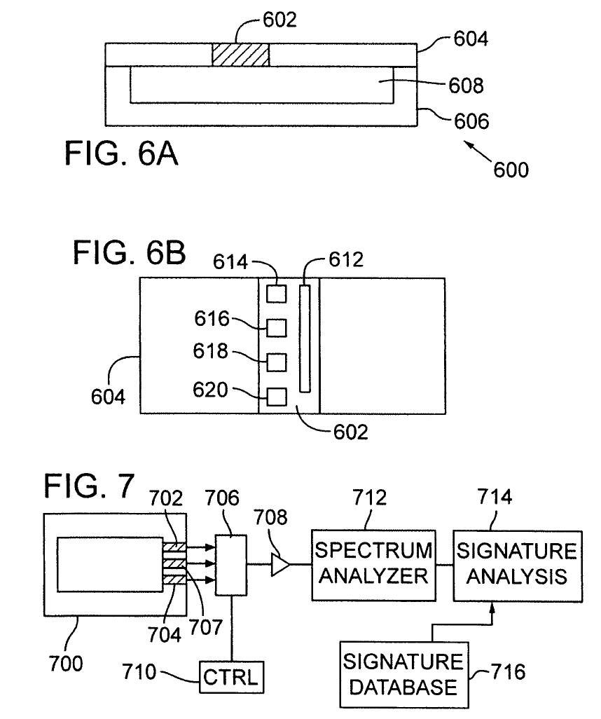

FIGS. 6A-6B construction of a sensor based on an alumina membrane 602 formed in a channel in a base substrate 604. The base substrate 604 is processed to define a channel in which aluminum is deposited. The aluminum is processed to form a nano-porous membrane, and portions of the base substrate are removed so that the alumina membrane extends completely through the remaining portion of the base substrate. A fluid chamber 608 is then defined with a channel piece 606. The base substrate and the channel piece are conveniently made of silicon for ease of manufacture.

As shown in FIG. 6B, conductors 612, 614, 616, 618, 620 can be used to define sensitized portions of the membrane 602. The membrane can be sensitized with, for example, antibodies. Alternatively, cells can be patterned onto the alumina membrane to investigate cell response to samples introduced into the chamber 606. For example, effects of a drug on a particular cell type can be investigated by recording electrical signals from the conductors 612, 614, 616, 618, 620 as a function of drug exposure.

A sectional view of another representative sensor 1100 is provided in a FIG. 11. The sensor 1100 includes a supporting substrate 1102 that typically has a surface 1103 on which conductors for electrical connections to nano-pores 1108 in a nano-porous membrane 1104. Additional electrical circuit components can also be situated on the surface 1103, or the supporting substrate 1102 can be processed to include circuit components. Sidewalls 1106 are provided to define analyte wells 1110, 1111. In a typical application, an analyte is supplied to only one of the wells 1110, 1111 and a control reagent is applied to the other. The supporting substrate can be silicon or a silicon compound having copper, gold, or other conductors on the surface 203, but the supporting substrate can also be glass or fused silica with indium tin oxide (ITO) conductors. Other combinations of materials can be used as convenient. A patterned conductor layer 1105 is generally provided to, for example, combine electrical outputs associated with a single well, or nano-pores of selected characteristics such as size, aspect ratio, or sensitization reagent.

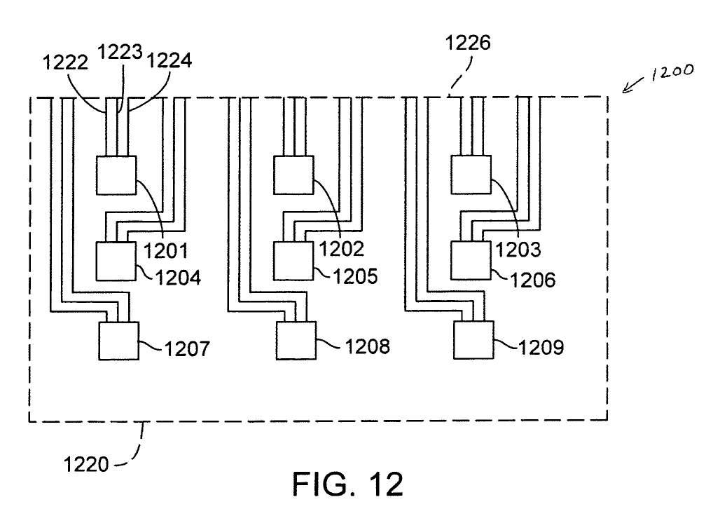

FIG. 12 illustrates a sensor assembly 1200 that includes an array of sensitized membrane sensors 1201-1209 situated in rows and columns on a substrate 1220. The sensors 1201-1209 include sensitized nano-porous membranes and base substrates that include electrical connections to the membranes. Each membrane can be sensitized and electrically connected for detection of a single analyte or a plurality of analytes. While nano-pores are typically sensitized for a single target analyte, interrogation using frequency domain signatures can permit a single nano-pore or set of nano-pores to be sensitized to a plurality of target analytes. As shown in FIG. 12, the sensor 1201 is coupled to conductors 1222, 1223, 1224 to accommodate as many as three sensitizations (two if one conductor is used as a reference). The remaining membrane sensors are similarly connected, but each sensor and its electrical connections can be differently configured. In the example of FIG. 12, electrical connections extend to a substrate edge 1226, but other arrangements can be used. Spacing of the membrane sensors 1201-1209 can be conveniently selected to corresponding to microtiter plate spacings so that microtiter based dispensing and other accessories can be used with the sensor assembly 1200.

A representative nano-porous membrane based sensor 1300 is illustrated in FIG. 13. A substrate 1302 is provided with a plurality of nano-pores 1304 or the like. As shown in FIG. 13, the nano-pores are all of the same size and are arranged in a series of rows and columns, but other arrangements of pores of the same or different sizes can be used. Regions 1306, 1308 contain respective pluralities of nano-pores that are electrically connected to a readout amplifier 1310. The readout amplifier is generally a differential amplifier, and produces an output signal based on a difference in an electrical characteristic of the nano-pores in the first region 1306 and the second region 1308. The electrical readout can be processed to obtain, for example, a spectrum (using, for example, a fast Fourier transform), a power spectral density, or to identify a particular spectral component associated with an intended response. The electrical readout can be configured to permit measurement of a time evolution of response so that, for example, spectrum as a function of exposure time is determined.

In some other examples, sensitized micro-cylindrical, spherical, ring, and disc or other waveguides can be used for analyte detection. Such waveguides can be conveniently fabricated on a doped (P- or Co-doped) or undoped silica layer on a silicon substrate. A resist layer such as a photoresist layer can be deposited on the doped silica layer, soft baked, exposed to define a pattern in the photoresist, and then developed to produce cylindrical microcavities 3 μm high and 950 μm in diameter, but other shapes and sizes can be similarly formed. In one example, the photoresist is Shipley 1827 photoresist that is spin coated to a 3 μm thickness.

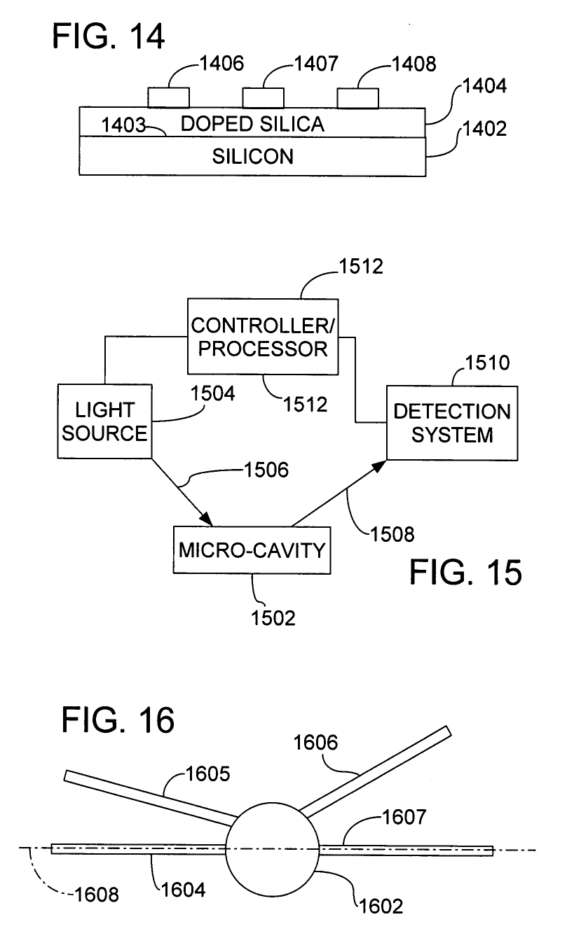

A representative array of optical cavities is illustrated in FIG. 14. A silicon substrate 1402 has a major surface 1403 on which a Co-doped or P-doped silica layer 1404 is situated. Developed photoresist portions 1406-1408 define one or more microcavities. Surfaces of the microcavities can be sensitized by exposure to sensitizer solutions such as MPO, CRP or other solutions as described above.

A representative system of interrogation of a microcavity such as shown in FIG. 14 is illustrated in FIG. 15. A light source 1504 is configured to deliver a light flux 1506 to a sensitized micro-cavity 1502. Typically the light flux 1506 is coupled to the micro-cavity 1502 with an optical fiber having a cleaved output surface or an etched, tapered optical fiber. An output light flux 1508 associated with an interaction of the incident flux and the micro-cavity 1502 (a “modulated” or “analyte-modulated” flux) is coupled to a detection system 1510 that produces an analog or digital electrical signal associated with the output flux 1508 that is coupled to a controller/processor 1512. The controller/processor 1512 can be conveniently implemented with a desktop, laptop, or palmtop computer, or other general purpose or dedicated processing system. A memory such as a random access memory or a disk drive is provided to store calibration parameters, control parameters, and measured data.

The light flux 1506 can be at visible, infrared, or other wavelengths. Detection can be based on phase sensitive detection using mechanical modulation of the light flux 1506 with a chopper or using an electrically modulated light source such as a laser diode or light emitting diode. While the detected light flux is indicative of the presence of an analyte, this flux is not necessarily a linear function of analyte exposure, and calibration values for different analytes are generally acquired. In one example, MPO detection is associated with a linear response, while CRP response is nonlinear.

In another example shown in FIG. 16, an optical cavity 1602 is defined by a portion of a polymer layer. Input/output waveguides 1604-1607 can be defined in the same polymer layer or otherwise provided, and interrogation optical fluxes and analyte-modulated optical fluxes can be communicated via these waveguides. Selected input/output waveguides can be along a common axis such as the waveguides 1604, 1607 that are along an axis 1608. The waveguides 1604-1607 can be single or multimode waveguides.

Polymer-based photoresists are convenient for microcavity fabrication, but other polymers can be used. In addition, either positive photoresists (resists that are more readily removed by a developer after exposure) or negative photoresists (resists that are less readily removed by a developer after exposure) can be used. A plurality of microcavities can be formed in a single series of process steps to produce substrates having a plurality of microcavities that can be sensitized for different analytes. Input/output waveguides can be conveniently formed along with the cavities in the same polymer layer. Such construction is referred to as unitary construction.

In view of the many possible embodiments to which the principles of the disclosed technology may be applied, it should be recognized that the illustrated embodiments are only preferred examples and should not be taken as limiting the scope of the invention. For convenience, sensitizations for CRP and MPO are described, but other sensitizations are possible such as sensitization for prostate specific antibody or other biomarkers. Photosensitive polymers other than photoresists can be used and can be selected so that either exposed or unexposed portions of the photopolymer layer remain as optical cavities. Substrates other than silica or silicon can be used, and arrays of microcavities having different geometries (linear, cylindrical, ring) can be defined on a single substrate. We claim as our invention all that comes within the scope and spirit of the appended claims.

We claim:

1. A sensor, comprising:
a substrate having defined thereon at least one polymer optical cavity; and
a sensitizing agent immobilized on at least a portion of an exterior of the polymer optical cavity.

2. The sensor of claim 1, further comprising:
a first polymer waveguide coupled to the polymer optical cavity and configured to deliver an optical interrogation flux to the polymer optical cavity.

3. The sensor of claim 2, further comprising:
a second polymer waveguide coupled to the polymer optical cavity and configured to receive an optical flux modulated based on the first sensitizing agent.

4. The sensor of claim 1, wherein the polymer optical cavity is a formed of a polymer photoresist.

5. The sensor of claim 1, wherein the substrate comprises a silica layer, and the polymer optical cavity is situated adjacent the silica layer.

6. The sensor of claim 1, wherein the polymer optical cavity is a cylindrical cavity.

7. The sensor of claim 6, wherein a diameter of the cylindrical cavity is between about 100 μm and 1.0 mm.

8. The sensor of claim 4, wherein the photoresist is a positive resist.

9. The sensor of claim 4, wherein the photoresist is a negative resist.

10. The sensor of claim 1, wherein the sensitizing agent is associated with at least one of CRP and MPO.

11. A sensor system, comprising:
a sensitized polymer optical cavity;
a light source coupled to provide an interrogation light flux to the polymer optical cavity; and
a detection system configured to receive a modulated portion of the interrogation light flux from the sensitized polymer cavity and provide an indication of an analyte concentration based on the received portion.

12. The sensor system of claim 11, further comprising;
an input waveguide configured to couple the interrogation light flux from the light source to the sensitized polymer cavity; and
an output waveguide configured to couple the modulated portion of the interrogation light flux to the detection system.

13. The sensor system of claim 12, wherein the input waveguide and the output waveguide are of unitary construction with the polymer optical cavity.

14. A method, comprising:
applying a photopolymer layer to a substrate;
exposing the photopolymer layer to a patterned light flux associated with at least one optical cavity;
developing the photopolymer so as to define the at least one optical cavity; and
applying a sensitizer to the at least one optical cavity.

15. The method of claim 14, wherein the photopolymer layer is a photoresist layer.

16. The method of claim 15, wherein the sensitizer is associated with selective bonding of at least one of MPO or CRP.

17. The method of claim 15, wherein the photoresist is a positive resist.

18. The method of claim 15, wherein the photoresist is a negative resist.

19. The method of claim 14, wherein the patterned light flux is based on at least one optical cavity and at least one waveguide coupled to the at least one optical cavity and the photopolymer is developed so as to define the at least one optical cavity and the at least one waveguide.

20. The method of claim 11, wherein the optical cavity is cylindrical.
